(19) United States
(12) Patent Application Publication
(10) Pub. No.: US 2025/0182834 A1
(43) Pub. Date: Jun. 5, 2025

(54) MEMORY DEVICE USING MULTIPLE MEMORY CELLS GROUPED TO JOINTLY STORE MULTIPLE BITS AND ASSOCIATED METHOD

(71) Applicant: MEDIATEK INC., Hsinchu City (TW)

(72) Inventors: Tzu-Hsien Yang, Hsinchu City (TW); Yi-Te Chiu, Hsinchu City (TW)

(73) Assignee: MEDIATEK INC., Hsinchu City (TW)

(21) Appl. No.: 18/954,428

(22) Filed: Nov. 20, 2024

Related U.S. Application Data
(60) Provisional application No. 63/604,233, filed on Nov. 30, 2023.

(51) Int. Cl. G11C 17/00; G11C 7/06; G11C 7/10; G11C 7/12; G11C 7/18; G11C 8/08; G11C 8/10

(52) U.S. Cl. CPC G11C 17/00; G11C 7/06; G11C 7/1069; G11C 7/1096; G11C 7/12; G11C 7/18; G11C 8/08; G11C 8/10

(57) ABSTRACT

A memory device includes memory cells, at least one word-line, bit-line groups, and a peripheral circuit. Each bit-line group includes multiple bit-lines. The peripheral circuit obtains first bits by reading the memory cells through the bit-line groups, respectively, when the memory cells are selected by the at least one word-line; and determines second bits stored in the memory cells by jointly considering the first bits. The number of the memory cells is smaller than the number of the second bits.

### CROSS REFERENCE TO RELATED APPLICATIONS

This application claims the benefit of U.S. Provisional Application No. 63/604,233, filed on Nov. 30, 2023. The content of the application is incorporated herein by reference.

### BACKGROUND

The present invention relates to a memory design, and more particularly, to a memory device using multiple memory cells (e.g., 2 memory cells) grouped to jointly store multiple bits (e.g., 3 bits) for achieving increased bit-density and lower power consumption.

Memory devices, such as read-only-memories (ROMs), are widely used in a variety of applications. Taking ROM for example, it is a non-volatile memory with fixed data that is programmed during a manufacturing process. For example, the fixed data stored in the ROM may be a boot-up code, basic input/output system (BIOS) firmware, and/or device drivers of a system on a chip (SoC). However, as an SoC design becomes more complex, a larger ROM capacity is needed. However, increasing the ROM capacity requires a larger die size, which increases the chip area and the power consumption of the SoC. To address this issue, a conventional solution is to use multi-level cell (MLC) ROM cells to increase the bit-density. For example, the conventional solution stores more than one bit of information per ROM cell by utilizing multiple VD (via-to-MD) vias in a single transistor area, where the VD vias may provide a means to connect an MD (metal-to-drain/source) layer to an M0 metal layer. However, this approach is not suitable for advanced process technology as it causes bit-line (BL) metal routing congestion, leading to larger cell area, slower performance, and higher power consumption. Thus, there is a need for an innovative ROM design with increased bit-density and lower power consumption.

### SUMMARY

One of the objectives of the claimed invention is to provide a memory device using multiple memory cells (e.g., 2 memory cells) grouped to jointly store multiple bits (e.g., 3 bits) for achieving increased bit-density and lower power consumption.

According to a first aspect of the present invention, an exemplary memory device is disclosed. The exemplary memory device includes a plurality of memory cells, at least one word-line, a plurality of bit-line groups, and a peripheral circuit. Each bit-line group includes a plurality of bit-lines. The peripheral circuit is arranged to obtain a plurality of first bits by reading the plurality of memory cells through the plurality of bit-line groups, respectively, when the plurality of memory cells are selected by the at least one word-line; and determine a plurality of second bits stored in the plurality of memory cells by jointly considering the plurality of first bits. A number of the plurality of memory cells is smaller than a number of the plurality of second bits.

According to a second aspect of the present invention, an exemplary method of writing data into a memory device is disclosed. The exemplary method includes: receiving an input data; performing a mapping operation upon the input data to convert the input data into a write data, wherein the write data includes a plurality of first bits, the input data includes a plurality of second bits, and the plurality of second bits are mapped to the plurality of first bits; and during a manufacturing process of the memory device, storing the write data into the memory device, wherein the memory device includes a plurality of memory cells, the plurality of first bits are stored in the plurality of memory cells, and a number of the plurality of memory cells is smaller than a number of the plurality of second bits.

According to a third aspect of the present invention, an exemplary method of reading data from a memory device is disclosed. The exemplary method includes: activating at least one word-line to select a plurality of memory cells; obtaining a plurality of first bits by reading the plurality of memory cells through a plurality of bit-line groups, respectively, wherein each of the plurality of bit-line groups includes a plurality of bit-lines; and determining a plurality of second bits stored in the plurality of memory cells by jointly considering the plurality of first bits. A number of the plurality of memory cells is smaller than a number of the plurality of second bits.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a memory device according to an embodiment of the present invention.

FIG. 2 is a diagram illustrating a peripheral circuit according to an embodiment of the present invention.

FIG. 3 is a diagram illustrating a decoder circuit according to an embodiment of the present invention.

FIG. 4 is a flowchart illustrating a write operation and a read operation performed upon the memory device shown in FIG. 1 according to an embodiment of the present invention.

FIG. 5 is a diagram illustrating a layout comparison between a typical 1×SLC ROM cell and a proposed 1.5×MLC ROM cell according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

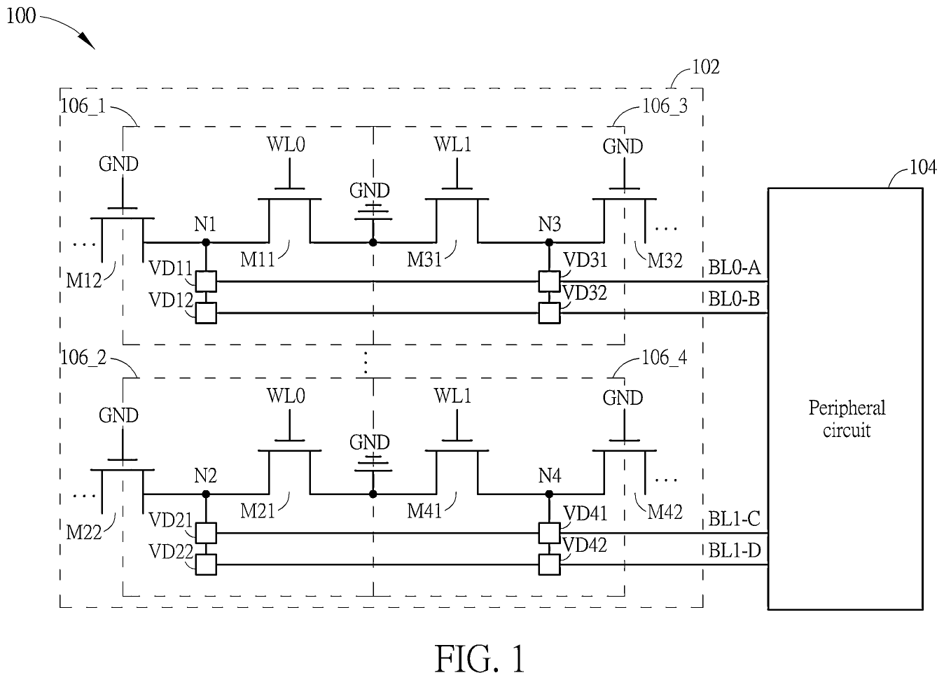

FIG. 1 is a diagram illustrating a memory device according to an embodiment of the present invention. The memory device 100 includes a memory array 102 and a peripheral circuit 104. The memory array 102 includes memory cells. For brevity and simplicity, only four memory cells 106_1, 106_2, 106_3, 106_4 are illustrated in FIG. 1. In this embodiment, each of the memory cells 106_1, 106_2, 106_3, 106_4 may be a read-only memory (ROM) cell composed of 1.5 transistors. Specifically, the memory cell 106_1 includes transistors M1 and M2, where the transistor M2 is shared with an adjacent memory cell (not shown) for isolation. The memory cell 106_2 includes transistors M21 and M22, where the transistor M22 is shared with an adjacent memory cell (not shown) for isolation. The memory cell 106_3 includes transistors M31 and M32, where the transistor M32 is shared with an adjacent memory cell (not shown) for isolation. The memory cell 106_4 includes transistors M41 and M42, where the transistor M42 is shared with an adjacent memory cell (not shown) for isolation.

The memory device 100 further includes word-lines (WLs) and bit-line (BL) groups, where each bit-line group includes a plurality of bit-lines. Each memory cell of the memory array 102 is located at an intersection of one word-line and one bit-line group (which includes multiple bit-lines). As shown in FIG. 1, a gate node of the transistor M11 is coupled to the word-line WL0, a gate node of the transistor M21 is coupled to the word-line WL0, a gate node of the transistor M31 is coupled to the word-line WL1, and a gate node of the transistor M41 is coupled to the word-line WL1. The memory cells 106_1 and 106_3 are coupled to the same bit-line group that includes two bit-lines BL0-A and BL0-B. The memory cells 106_2 and 106_4 are coupled to the same bit-line group that includes two bit-lines BL1-C and BL1-D. In this embodiment, the memory cells 106_1 and 106_2 are grouped to jointly store multiple bits (e.g., 2 bits), and the memory cells 106_3 and 106_4 are grouped to jointly store multiple bits (e.g., 2 bits). It should be noted that the memory cells 106_1 and 106_2 may be selected by the same word-line or different word-lines, depending upon actual design considerations. Similarly, the memory cells 106_3 and 106_4 may be selected by the same word-line or different word-lines, depending upon actual design considerations.

During the manufacturing process of the memory device (e.g., ROM device) 100, data is stored in the memory cell (e.g., ROM cell) 106_1 through the VD layer located at the transistor source node N1, data is stored in the memory cell (e.g., ROM cell) 106_2 through the VD layer located at the transistor source node N2, data is stored in the memory cell (e.g., ROM cell) 106_3 through the VD layer located at the transistor source node N3, and data is stored in the memory cell (e.g., ROM cell) 106_4 through the VD layer located at the transistor source node N4. For example, when a VD via VD11 is fabricated during the manufacturing process of the memory device (e.g., ROM device) 100, the bit-line BL0-A is coupled to the transistor source node N1 through the VD via VD11, and can be coupled to a reference voltage (e.g., a ground voltage GND) when the transistor M11 is turned on by the word-line WL0 (i.e., the memory cell 106_1 is selected by the word-line WL0) during a normal operation. Hence, a data value of “0” is indicted by the VD layer's connection to the ground voltage GND. For another example, when the VD via VD11 is not fabricated during the manufacturing process of the memory device (e.g., ROM device) 100, the bit-line BL0-A is disconnected from the transistor source node N1, and is isolated from the reference voltage (e.g., ground voltage GND) when the transistor M11 is turned on by the word-line WL0 (i.e., the memory cell 106_1 is selected by the word-line WL0) during the normal operation. Hence, a data value of “1” is indicted by the absence of the VD layer's connection and the transistor source node N1 being floating.

Similarly, a data value of “0” is indicted by the presence of VD via VD12 being connected to the transistor source node N1, and a data value of “1” is indicted by the absence of VD via VD12 and the transistor source node N1 being floating; a data value of “0” is indicted by the presence of VD via VD21 being connected to the transistor source node N2, and a data value of “1” is indicted by the absence of VD via VD21 and the transistor source node N2 being floating; a data value of “0” is indicted by the presence of VD via VD22 being connected to the transistor source node N2, and a data value of “1” is indicted by the absence of VD via VD22 and the transistor source node N2 being floating; a data value of “0” is indicted by the presence of VD via VD31 being connected to the transistor source node N3, and a data value of “1” is indicted by the absence of VD via VD31 and the transistor source node N3 being floating; a data value of “0” is indicted by the presence of VD via VD32 being connected to the transistor source node N3, and a data value of “1” is indicted by the absence of VD via VD32 and the transistor source node N3 being floating; a data value of “0” is indicted by the presence of VD via VD41 being connected to the transistor source node N4, and a data value of “1” is indicted by the absence of VD via VD41 and the transistor source node N4 being floating; and a data value of “0” is indicted by the presence of VD via VD42 being connected to the transistor source node N4, and a data value of “1” is indicted by the absence of VD via VD42 and the transistor source node N4 being floating.

In accordance with the proposed high-density, low-power memory design, M memory cells are jointly used to store N bits, and each memory cell can be accessed by one bit-line group including K bit-lines and is capable of supporting (K+1) bit combinations, where N>M and/or N>K. The peripheral circuit 104 is arranged to determine N bits stored in M memory cells according to M*K bits delivered over M*K bit-lines included in the corresponding M bit-line groups when the M memory cells are selected by at least one word-line. Specifically, when M memory cells are selected by at least one word-line, the peripheral circuit 104 obtains M*K bits by reading M memory cells through M bit-line groups, respectively, and determines N bits stored in the M memory cells by jointly considering the M*K bits. Regarding the embodiment shown in FIG. 1, 2 (M=2) memory cells (e.g., ROM cells) are jointly used to store 3 (N=3) bits, and each memory cell can be accessed by one bit-line group including 2 (K=2) bit-lines and is capable of supporting 3 (K+1=3) bit combinations such as (1, 1), (0, 1), and (1, 0).

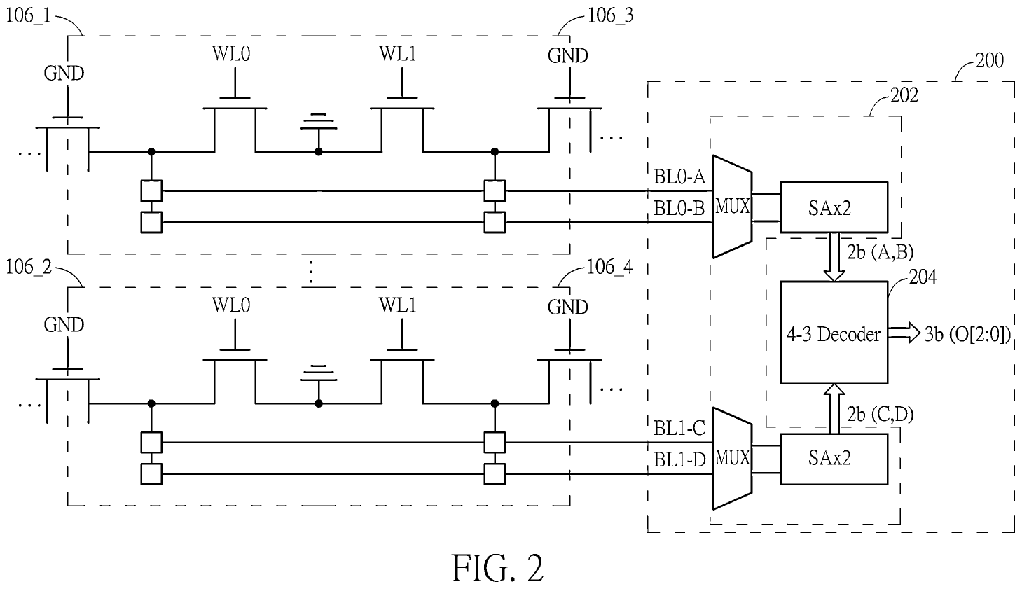

FIG. 2 is a diagram illustrating a peripheral circuit according to an embodiment of the present invention. The peripheral circuit 104 shown in FIG. 1 may be implemented using the peripheral circuit 200 shown in FIG. 2. The peripheral circuit 200 includes a sense amplifier (SA) circuit 202 and a decoder circuit (labeled by “4-3 decoder”) 204. The sense amplifier circuit 202 may include multiplexers (labeled by “MUX”) and sense amplifiers (labeled by “SAx2”). In this embodiment, the memory cells 106_1 and 106_2 are jointly used to store 3 bits. When the memory cells 106_1 and 106_2 are selected by the word-line WL0, the sense amplifier circuit 202 is arranged to obtain four bits, including one bit A delivered over bit-line BL0-A, one bit B delivered over bit-line BL0-B, one bit C delivered over bit-line BL1-C, and one bit D delivered over bit-line BL1-D. The decoder circuit 204 is arranged to decode four bits A, B, C, D output from the sense amplifier circuit 202, to generate and output 3 bits O[2:0] that are stored using two memory cells 106_1 and 106_2. Specifically, the decoder circuit 204 may be a 4-to-3 decoder that receives four bits (A, B, C, D) as its decoder input and generates 3 bits (O[2], O[1], O[0]) as its decoder output, where each of the bit combinations (A, B) and (C, D) is one of 3 possible bit combinations such as (1, 1), (1, 0), (0, 1), and the bit combination (O[2], O[1], O[0]) is one of 8 possible bit combinations such as (0, 0, 0), (0, 0, 1), (0, 1, 0), (1, 0, 1), (1, 0, 0), (0, 1, 1), (1, 1, 0), (1, 1, 1). One possible implementation of the mapping between a 4-bit decoder input (A, B, C, D) and a 3-bit decoder output (O[2], O[1], O[0]) is shown in the following table.

TABLE 1

| Cell-0 | | Cell-1 | | O [2] | O [1] | O [0] | O [2:0] |
|---|---|---|---|---|---|---|---|
| A | B | C | D | (Binary) | (Binary) | (Binary) | (Decimal) |
| 1 | 1 | 1 | 1 | 0 | 0 | 0 | 0 |
| 1 | 1 | 0 | 1 | 0 | 0 | 1 | 1 |
| 1 | 1 | 1 | 0 | 0 | 1 | 0 | 2 |
| 0 | 1 | 1 | 1 | 1 | 0 | 1 | 5 |
| 0 | 1 | 0 | 1 | 1 | 0 | 0 | 4 |
| 0 | 1 | 1 | 0 | 0 | 1 | 1 | 3 |
| 1 | 0 | 1 | 1 | 1 | 1 | 0 | 6 |
| 1 | 0 | 0 | 1 | 1 | 1 | 1 | 7 |
| 1 | 0 | 1 | 0 | X | X | X | X |
| (X) | (X) | (X) | (X) | | | | |

Since each of the bit combinations (A, B) and (C, D) is one of 3 possible bit combinations such as (1, 1), (1, 0), (0, 1), there are 3*3 possible bit combinations for (A, B) and (C, D). Since 3 bits are stored using 2 memory cells, only 23 bit combinations among the 3*3 possible bit combinations are actually used. In this example, the last 4-bit combination (A, B, C, D)=(1, 0, 1, 0) is treated as an invalid bit combination.

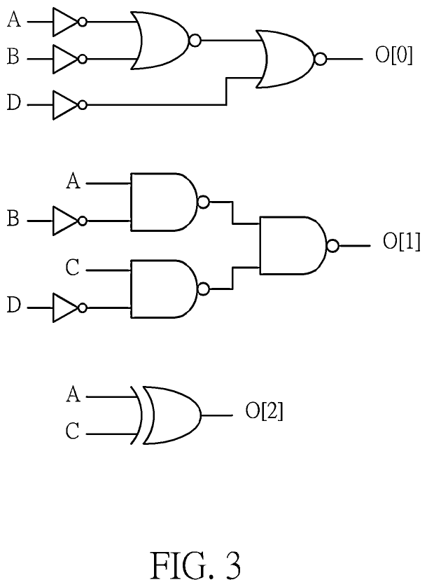

FIG. 3 is a diagram illustrating a decoder circuit according to an embodiment of the present invention. The decoder circuit 204 shown in FIG. 2 may be implemented using the decoder circuit 300 shown in FIG. 3. The decoder circuit 300 is designed to support these decoding rules listed in above table. In this embodiment, the decoder circuit 300 includes a plurality of NOT gates, a plurality of NOR gates, a plurality of NAND gates, and an XOR gate.

It should be noted that the mapping between a 4-bit decoder input (A, B, C, D) and a 3-bit decoder output (O[2], O[1], O[0]) as shown in the above table is for illustrative purposes only, and is not meant to be a limitation of the present invention. For example, in an alternative 4-to-3 decoder design, a different selection of 23 bit combinations among the 3*3 possible bit combinations may be used. To put it simply, the mapping between a 4-bit decoder input (A, B, C, D) and a 3-bit decoder output (O[2], O[1], O[0]) and logic gates used by the decoder circuit 204 for achieving 4-to-3 decoding may be adjusted, depending upon actual design considerations.

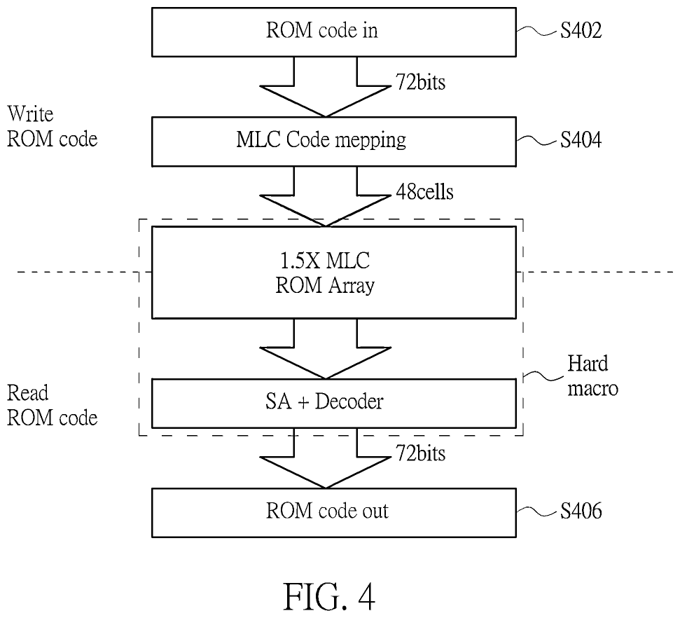

In this embodiment, the memory device 100 shown in FIG. 1 is a ROM device. Hence, data is stored into the memory device 100 during a manufacturing process of the memory device 100, and stored data is read from the memory device 100 during a normal operation of the memory device 100. FIG. 4 is a flowchart illustrating a write operation and a read operation performed upon the memory device 100 shown in FIG. 1 according to an embodiment of the present invention. At step S402, an input data to be stored in the memory device (e.g., ROM device) 100 is received. For example, the input data may be a ROM code of an SoC that uses the memory device (e.g., ROM device) 100. As mentioned above, the memory device (e.g., ROM device) 100 may be designed to store 3 bits in 2 memory cells, where 3 bits stored in 2 memory cells are represented by a 4-bit combination with 2 bits indicated by 2 VD layer's connection statues (absence/presence) of one memory cell and 2 bits indicated by 2 VD layer's connection statues (absence/presence) of the other memory cell. Hence, at step S402, a mapping operation is performed upon the input data (e.g., ROM code) to convert the input data (e.g., ROM code) into a write data (e.g., MLC code). For example, the input data (e.g., ROM code) may include 3 raw bits (e.g., O[2], O[1], O[0]), and the write data (e.g., MLC code) may include 4 encoded bits (e.g., A, B, C, D), where the raw bits (e.g., O[2], O[1], O[0]) are mapped to the encoded bits (e.g., A, B, C, D) through a 3-to-4 encoding process.

During a manufacturing process of the memory device (e.g., ROM device) 100, the write data (e.g., MLC code) is stored into the memory device (e.g., ROM device) 100 through the VD layer. For example, the memory device (e.g., ROM device) 100 includes two memory cells 106_1 and 106_2 grouped to jointly store 3 raw bits (e.g., O[2], O[1], O[0]) of the input data (e.g., ROM code) by using 4 VD layer's connection statues (absence/presence) to store/indicate 4 encoded bits (e.g., A, B, C, D) that are indicative of the 3 raw bits (e.g., O[2], O[1], O[0]).

After the manufacturing process of the memory device (e.g., ROM device) 100, the stored data in the memory device (e.g., ROM device) 100 can be read out for processing. The ROM data (e.g., A, B, C, D) is read and decoded to a binary code (e.g., O[2], O[1], O[0]) inside the hard macro. For example, the word-line WL0 is activated to select the memory cells 106_1 and 106_2; the sense amplifier circuit 202 obtains 4 bits (A, B, C, D) by reading the memory cells 106_1 and 106_2 through two bit-line groups, respectively, where 2 bits (A, B) are obtained through one bit-line group including bit-lines BL0-A and BL0-B, and 2 bits (C, D) are obtained through another bit-line group including bit-lines BL1-C and BL1-D; and the decoder circuit 204 determines 3 bits (O[2], O[1], O[0]) stored in the memory cells 106_1 and 106_2 by decoding 4 bits (A, B, C, D) output from the sense amplifier circuit 202. At step S406, the decoder circuit 204 outputs the ROM code to the SoC for processing.

In some embodiments of the present invention, M memory cells grouped to jointly store N (N>M) bits may be placed in adjacent locations. For example, the memory cells 106_1 and 106_2 may be adjacent memory cells in the memory array 102, and the memory cells 106_3 and 106_4 may be adjacent memory cells in the memory array 102. However, this is for illustrative purposes only, and is not meant to be a limitation of the present invention. In some embodiments of the present invention, the M memory cells grouped to jointly store N (N>M) bits may be accessed by different input/output (I/O) circuits or may be included in different memory macros. For example, the memory cells 106_1 and 106_2 may be non-adjacent memory cells in the memory array 102, and the memory cells 106_3 and 106_4 may be non-adjacent memory cells in the memory array 102. This flexibility allows designers to optimize the placement of memory cells to improve memory access performance and design efficiency.

As mentioned above, the memory device (e.g., ROM device) 100 may be designed to store 3 bits in 2 memory cells (e.g., ROM cells), where 3 bits stored in 2 memory cells are represented by a 4-bit combination with 2 bits indicated by 2 VD layer's connection statues (absence/presence) of one memory cell and 2 bits indicated by 2 VD layer's connection statues (absence/presence) of the other memory cell. Hence, one bit-line group including two bit-lines is used to read 2 VD layer's connection statues (absence/presence) from one memory cell. Due to the fact that only two bit-lines are needed to read 2 VD layer's connection statues (absence/presence) from one memory cell, each memory cell of the memory device 100 may utilize same metal routing resources as a single-level cell (SLC) memory cell. Since 2 memory cells are grouped to jointly store 3 bits, each memory cell may be regarded as a 1.5×MLC for storing 1.5 bits.

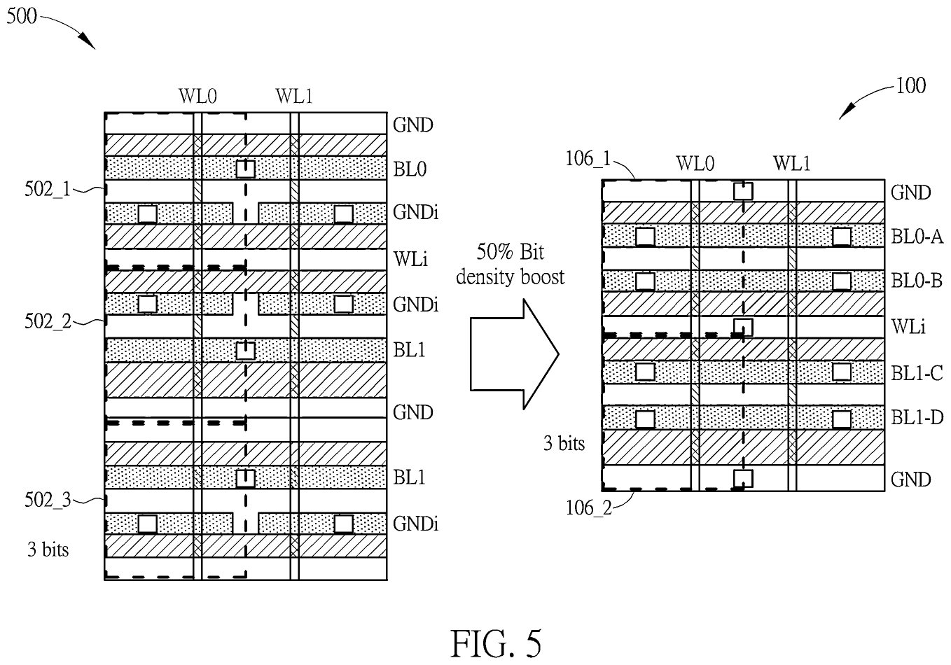

FIG. 5 is a diagram illustrating a layout comparison between a typical 1×SLC ROM cell and a proposed 1.5×MLC ROM cell according to an embodiment of the present invention. The left part of FIG. 5 illustrates a top view of an exemplary layer design of the typical memory device 500 composed of 1×SLC ROM cells. The right part of FIG. 5 illustrates a top view of an exemplary layer design of the proposed memory device 100 composed of 1.5×MLC ROM cells. Due to inherent characteristics of the typical 1×SLC ROM cell, 3 SLC ROM cells 502_1, 502_2, 502_3 of the typical memory device 500 are used to store 3 bits of the ROM code, respectively. However, the proposed memory device 100 only needs two MLC ROM cells (e.g., memory cells 106_1 and 106_2) to store the same 3 bits of the ROM code. As shown in FIG. 5, each of the MLC ROM cells (e.g., memory cells 106_1 and 106_2) of the proposed memory device 100 utilizes same metal routing resources as a typical SLC memory cell (e.g., SLC ROM cell 502_1/502_2/502_3). Hence, the proposed memory device 100 is suitable for advanced process technology due to no BL routing congestion issue. Furthermore, the proposed 1.5×MLC ROM cell and the typical 1×SLC ROM cell may have the same size (i.e., same width and same height). Compared to the typical memory device 500 using 1×SLC ROM cells, the proposed memory device 100 using 1.5×MLC ROM cell has 50% bit-density boost under the same area. In summary, the memory device 100 using the proposed 1.5×MLC ROM cells can achieve increased bit-density and low power consumption compared to typical SLC ROM devices and typical MLC ROM devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory device comprising:
a plurality of memory cells;
at least one word-line;
a plurality of bit-line groups, each comprising a plurality of bit-lines; and
a peripheral circuit, arranged to:
obtain a plurality of first bits by reading the plurality of memory cells through the plurality of bit-line groups, respectively, when the plurality of memory cells are selected by the at least one word-line; and
determine a plurality of second bits stored in the plurality of memory cells by jointly considering the plurality of first bits;
wherein a number of the plurality of memory cells is smaller than a number of the plurality of second bits.

2. The memory device of claim 1, wherein a number of the plurality of bit-lines of each bit-line group is smaller than the number of the plurality of second bits.

3. The memory device of claim 1, wherein each of the plurality of memory cells is a read-only memory (ROM) cell.

4. The memory device of claim 1, wherein each of the plurality of memory cells utilizes same metal routing resources as a single-level cell (SLC) memory cell.

5. The memory device of claim 1, wherein a number of the plurality of bit-lines is equal to 2.

6. The memory device of claim 1, wherein the number of the plurality of memory cells is equal to 2.

7. The memory device of claim 1, wherein the number of the plurality of second bits is equal to 3.

8. The memory device of claim 1, wherein the plurality of memory cells are adjacent memory cells.

9. The memory device of claim 1, wherein the plurality of memory cells are non-adjacent memory cells.

10. The memory device of claim 1, wherein the peripheral circuit comprises:
a sense amplifier (SA) circuit, arranged to obtain the plurality of first bits each delivered over one bit-line included in the plurality of bit-line groups; and
a decoder circuit, arranged to decode the plurality of first bits to generate and output the plurality of second bits.

11. A method of writing data into a memory device, comprising:
receiving an input data;
performing a mapping operation upon the input data to convert the input data into a write data, wherein the write data comprises a plurality of first bits, the input data comprises a plurality of second bits, and the plurality of second bits are mapped to the plurality of first bits; and
during a manufacturing process of the memory device, storing the write data into the memory device, wherein the memory device comprises a plurality of memory cells, the plurality of first bits are stored in the plurality of memory cells, and a number of the plurality of memory cells is smaller than a number of the plurality of second bits.

12. The method of claim 11, wherein each of the plurality of memory cells is a read-only memory (ROM) cell.

13. The method of claim 11, wherein the number of the plurality of memory cells is equal to 2.

14. The method of claim 11, wherein the number of the plurality of second bits is equal to 3.

15. A method of reading data from a memory device, comprising:
activating at least one word-line to select a plurality of memory cells;
obtaining a plurality of first bits by reading the plurality of memory cells through a plurality of bit-line groups, respectively, wherein each of the plurality of bit-line groups comprises a plurality of bit-lines; and
determining a plurality of second bits stored in the plurality of memory cells by jointly considering the plurality of first bits;
wherein a number of the plurality of memory cells is smaller than a number of the plurality of second bits.

16. The method of claim 15, wherein each of the plurality of memory cells is a read-only memory (ROM) cell.

17. The method of claim 15, wherein a number of the plurality of bit-lines of each bit-line group is smaller than the number of the plurality of second bits.

18. The method of claim 15, wherein a number of the plurality of bit-lines is equal to 2.

19. The method of claim 15, wherein the number of the plurality of memory cells is equal to 2.

20. The method of claim 15, wherein the number of the plurality of second bits is equal to 3.
